(19) United States
(12) Patent Application Publication
(10) Pub. No.: US 2025/0194124 A1
(43) Pub. Date: Jun. 12, 2025

(54) SEMICONDUCTOR DEVICE AND METHOD OF MANUFACTURING THE SAME

(71) Applicants: HYUNDAI MOTOR COMPANY, Seoul (KR); KIA CORPORATION, Seoul (KR)

(72) Inventors: NackYong Joo, Hwaseong-si (KR); Dae Hwan Chun, Hwaseong-si (KR); Jungyeop Hong, Hwaseong-si (KR); Taehyun Kim, Hwaseong-si (KR); Youngkyun Jung, Hwaseong-si (KR); Junghee Park, Hwaseong-si (KR)

(73) Assignees: HYUNDAI MOTOR COMPANY, Seoul (KR); KIA CORPORATION, Seoul (KR)

(21) Appl. No.: 18/756,902

(22) Filed: Jun. 27, 2024

(30) Foreign Application Priority Data
Dec. 11, 2023 (KR) 10-2023-0178629

(51) Int. Cl. H01L 29/861; H01L 29/66

(52) U.S. Cl. CPC H10D 8/411; H10D 8/045

(57) ABSTRACT

A semiconductor device and a method of manufacturing the same are provided. The semiconductor device includes a substrate and an epi layer on an upper surface of the substrate. The semiconductor device also includes a P region located within the epi layer, at least one N+ region located within the P region, and at least one insulating layer in contact with the epi layer, the epi layer, the P region, and the at least one N+ region. The semiconductor device further includes an anode on the P region, the N+ region, and the insulating layer.

### CROSS-REFERENCE TO RELATED APPLICATION

This application claims priority to and the benefit of Korean Patent Application No. 10-2023-0178629 filed in the Korean Intellectual Property Office on Dec. 11, 2023, the entire contents of which are hereby incorporated herein by reference.

### BACKGROUND

### (a) Technical Field

The present disclosure relates to a semiconductor device and a method of manufacturing the same.

### (b) Description of the Related Art

A diode is a two-terminal device that can conduct current in one direction. In particular, diodes for power semiconductors for switching require high voltage and large current.

Because diode devices have different electrical characteristics depending on the structures, appropriate devices are used depending on application fields. However, the diode devices commonly require high current density, a low turn-on voltage, a high breakdown voltage, a low leakage current, and a fast switching speed. In order to simultaneously satisfy these requirements, various structures have been proposed. The most generally-used diode structure is a PN diode made of a PN junction, where an intrinsic region is added to the PN diode to secure high voltage characteristics used for power semiconductors.

### SUMMARY

An embodiment provides a semiconductor device with a reduced turn-on voltage and increased current density in an on-state.

Another embodiment provides a method of manufacturing the semiconductor device.

According to an embodiment, a semiconductor device is provided. The semiconductor device includes a substrate, an epi layer on an upper surface of the substrate, and a P region located within the epi layer. The semiconductor device also includes at least one N+ region located within the P region and at least one insulating layer in contact with the epi layer, the P region, and the at least one N+ region. The semiconductor device further includes an anode on the P region, the at least one N+ region, and the at least one insulating layer.

The at least one insulating layer may be located on an upper surface of the epi layer, the P region and the N+ region. The at least one insulating layer may be located in a trench structure along sides of the P region and the N+ region within the epi layer.

The substrate may include at least one of an N+ type substrate, a P+ type substrate, or any combination thereof.

The epi layer may include at least one of an N− type epi layer, a P− type epi layer, or any combination thereof.

The semiconductor device may further include a P-well region or an N-well region located between the epi layer and the P region within the epi layer.

The semiconductor device may further include a P-well region located between the epi layer and the P region within the epi layer. The semiconductor device may also include an N region located between the P-well region and the P region.

The P region may include a P+ type.

The at least one N+ regions may include a number of N+ regions in the range of two to four N+ regions. The at least one insulating layer may include a number of insulating layers in the range of two to four insulating layers.

The semiconductor device may further include a cathode located on a lower surface of the substrate or spaced apart in the same layer as the anode.

In the semiconductor device, an inversion channel may be formed in a portion where the P region and the insulating layer contact each other in an on state.

According to another embodiment, a method of manufacturing a semiconductor device is provided. The method includes forming an epi layer on an upper surface of the substrate. The method also includes forming a P region in the epi layer through ion implantation. The method additionally includes forming at least one N+ region within the P region through ion implantation. The method further includes forming at least one insulating layer at a location in contact with the epi layer, the P region, and the at least one N+ region. The method further still includes forming an anode on the P region, the at least one N+ region, and the at least one insulating layer.

Forming the P region may include patterning by placing a mask on the epi layer before the ion implantation.

Forming the N+ region may include patterning by placing a mask on the P region and the epi layer before the ion implantation.

Forming the insulating layer may include forming the insulating layer on upper surfaces of the epi layer, the P region, and the at least one N+ region, or forming the insulating layer in a trench structure along sides of the P region and the at least one N+ region within the epi layer.

The method may include, after forming the epi layer and before forming the P region, forming a P-well region or an N-well region within the epi layer between the epi layer and the P region.

The method may further include, after forming the epi layer and before forming the P region, forming a P-well region within the epi layer between the epi layer and the P region. The method may also include forming an N region between the P-well region and the P region.

Forming the at least one N+ region may include forming a number of N+ regions in the range of two to four N+ regions through ion implantation in the P region. Forming the at least one insulating layer may include forming a number of insulating layers in the range of two to four insulating layers on upper surfaces of the epi layer, the P region, and the N+ region.

The method may further include, after forming the anode, forming a cathode on a lower surface of the substrate or spaced apart in the same layer as the anode.

The semiconductor device according to an embodiment has a reduced turn-on voltage, enabling diode operation without a cut-in voltage, and increasing current density in the on state.

### BRIEF DESCRIPTION OF THE DRAWINGS

FIG. 1 is a view illustrating a cross section of a semiconductor device according to an embodiment.

FIG. 2A is a view schematically illustrating an operation mechanism in an on state of a semiconductor device according to an embodiment.

FIG. 2B is a view schematically illustrating an operation mechanism of a semiconductor device in an off state according to an embodiment.

FIG. 3A is a view schematically showing an operation mechanism under a condition of turn-on voltage (Vₜᵤᵣₙ₋ₒₙ)≤applied voltage (V_{AK})≤built-in voltage (V_{bi}) in the on state of a semiconductor device according to an embodiment.

FIG. 3B is a view schematically showing an operation mechanism under a condition of built-in voltage (V_{bi})≤applied voltage (V_{AK}) in the on state of a semiconductor device according to an embodiment.

FIG. 4 is a cross-sectional view of a semiconductor device according to another embodiment.

FIG. 5 is a cross-sectional view of a semiconductor device according to another embodiment.

FIG. 6 is a cross-sectional view of a semiconductor device according to another embodiment.

FIG. 7 is a cross-sectional view of a semiconductor device according to another embodiment.

FIG. 8 is a cross-sectional view of a semiconductor device according to another embodiment.

FIGS. 9A-9E are views sequentially showing a method of manufacturing a semiconductor device according to an embodiment.

FIGS. 10A-10E are views sequentially showing a method of manufacturing a semiconductor device according to another embodiment.

FIG. 11 is a linear scale graph showing the current density in the on state of a semiconductor devices according to an embodiment and a comparative example.

FIG. 12 is a log scale graph showing the current density in the on state of a semiconductor devices according to an embodiment and a comparative example.

### DETAILED DESCRIPTION

The advantages, features, and aspects described hereinafter should become more apparent from the following description of the embodiments with reference to the accompanying drawings. However, the present disclosure should not be construed as being limited to the embodiments set forth herein. Although not specifically defined, all of the terms including the technical and scientific terms used herein have meanings understood by those having ordinary skill in the art to which the present disclosure pertains. The terms defined in a generally-used dictionary should not be interpreted ideally or exaggeratedly unless clearly defined in the present specification. In addition, unless explicitly described to the contrary, the terms such as “comprise”, “include”, and the like, and variations such as “comprises”, “comprising”, “includes”, “including”, and the like, should be understood to imply the inclusion of stated elements but not the exclusion of any other elements.

Further, the singular includes the plural unless mentioned otherwise.

In the drawings, the thickness of layers, films, panels, regions, etc., are exaggerated for clarity. Like reference numerals designate like elements throughout the specification.

It should be understood that when an element such as a layer, film, region, or substrate is referred to as being “on” another element, the element can be directly on the other element or intervening elements may also be present. In contrast, when an element is referred to as being “directly on” another element, there are no intervening elements present.

When a component, device, element, or the like of the present disclosure is described as having a purpose or performing an operation, function, or the like, the component, device, or element should be considered herein as being “configured to” meet that purpose or perform that operation or function.

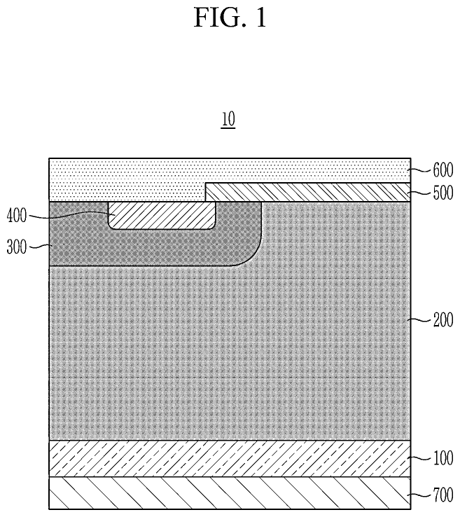

Semiconductor devices according to embodiments are described below with reference to FIGS. 1-8B.

FIG. 1 is a view illustrating a cross section of a semiconductor device according to an embodiment.

Referring to FIG. 1, a semiconductor device 10 according to an embodiment includes a substrate 100, an epi layer 200, a P region 300, an N+ region 400, an insulating layer 500, an anode 600, and a cathode 700.

The substrate 100 may include an N+ type substrate, a P+ type substrate, or a combination thereof.

The N+ type substrate may include, for example, a material such as N+ type silicon carbide (SiC), N+ type gallium nitride (GaN), N+ type gallium oxide (Ga₂O₃), N+ type diamond, N+ type silicon (Si), N+ type gallium arsenide (GaAs), N+ type germanium (Ge), N+ type aluminum nitride (AlN), or the like. The P+ type substrate may include, for example, a material such as P+ type silicon carbide (SiC), P+ type gallium nitride (GaN), P+ type gallium oxide (Ga₂O₃), P+ type diamond, P+ type silicon (Si), P+ type gallium arsenide (GaAs), P+ type germanium (Ge), P+ type aluminum nitride (AlN), or the like.

The epi layer 200 is an epitaxial layer and is located on the upper surface of the substrate 100.

The epi layer 200 may include an N− type epi layer, a P− type epi layer, or a combination thereof.

The N− type epi layer may include, for example, a material such as N− type silicon carbide (SiC), N− type gallium nitride (GaN), N− type gallium oxide (Ga₂O₃), N− type diamond, N− type silicon (Si), N− type gallium arsenide (GaAs), N− type germanium (Ge), N− type aluminum nitride (AlN), and the like. The P− type epi layer may include, for example, a material such as P− type silicon carbide (SiC), P− type gallium nitride (GaN), P− type gallium oxide (Ga₂O₃), P− type diamond, P− type silicon (Si), P− type gallium arsenide (GaAs), P− type germanium (Ge), P− type aluminum nitride (AlN), or the like.

For example, the substrate 100 may be an N+ type substrate, and the epi layer 200 may be an N− type epi layer.

The P region 300 is located within the epi layer 200. The upper surface of the epi layer 200 and the upper surface of the P region 300 may be located on the same line.

The P region 300 may be formed through an ion implantation process.

The P region 300 may include a P type semiconductor material, for example P type silicon carbide (SiC), P type gallium nitride (GaN), P type gallium oxide (Ga₂O₃), P type diamond, P type silicon (Si), P type gallium arsenide (GaAs), P type germanium (Ge), P type aluminum nitride (AlN), or the like.

The N+ region 400 may be located within the P region 300. The upper surface of the P region 300 and the upper surface of the N+ region 400 may be located on the same line.

One or more N+ region 400 may be included within the P region 300. For example, one N+ region 400 may be included as shown in FIG. 1. As another examples, two to four N+ regions 400 may be included.

The N+ region 400 may be formed through an ion implantation process.

The N+ region 400 may include an N+ type semiconductor material, for example N+ type silicon carbide (SiC), N+ type gallium nitride (GaN), N+ type gallium oxide (Ga₂O₃), N+ type diamond, N+ type silicon (Si), N+ type gallium arsenide (GaAs), N+ type germanium (Ge), N+ type aluminum nitride (AlN), or the like.

The insulating layer 500 may be located in contact with the epi layer 200, the P region 300, and the N+ region 400. For example, the insulating layer 500 may be located on the upper surfaces of the epi layer 200, the P region 300, and the N region 400.

The semiconductor device 10 according to an embodiment may include one or more insulating layers 500. For example, one insulating layer 500 may be included as shown in FIG. 1. As another example, two to four insulating layers 500 may be included.

The insulating layer 500 may include at least one of silicon dioxide (SiO₂), aluminum oxide (Al₂O₃), hafnium oxide (HfO₂), zirconium oxide (ZrO₂), or any combination thereof.

The anode 600 may be located on the P region 300, the N+ region 400, and the insulating layer 500. The anode 600 may include, for example, an ohmic metal.

The cathode 700 may be located on the lower surface of the substrate 100. The cathode 700 may include, for example, an ohmic metal.

A diode based on a PN junction has a built-in voltage due to the PN junction and can operate in the on state only when a voltage higher than this voltage is applied. The voltage before the diode turns on and conducts is referred to as cut-in voltage, threshold voltage, built-in voltage, etc.

The built-in voltage (V_{bi}) caused by the PN junction is determined by the N region doping concentration (N_{d}) and the P region doping concentration (Nₐ) as shown in Equation 1. The built-in voltage (V_{bi}) is inevitably generated. Therefore, current is not conducted in the region of 0<applied voltage (V_{AK})<built-in voltage (V_{bi}) region, which causes a decrease in output voltage during diode rectification. As shown in Equation 1, since the voltage is inversely proportional to the intrinsic concentration (nᵢ), power semiconductor materials with low intrinsic concentration, such as SiC, GaN, Ga₂O₃, and diamond, have a higher built-in voltage, and, accordingly, a higher cut-in voltage, which becomes a factor in increasing power consumption.

$${V}_{bi} = \frac{kT}{q} ln \frac{{N}_{d} {N}_{a}}{{n}_{i}^{2}} \qquad [ Equation 1 ]$$

The semiconductor device 10 according to an embodiment has a structure that reduces a turn-on voltage by using a metal oxide semiconductor (MOS) channel. In other words, the semiconductor device 10 may realize a lower turn-on voltage than a theoretical limit turn-on voltage of a typical diode structure. In an embodiment, the structure of the semiconductor device 10 may achieve a turn-on voltage of about 0 V or negative (−) voltages, which may not be achieved by the typical diode structure. As a result, the semiconductor device 10 may perform the rectification operation even in a region where rectification operation may not be implanted by the conventional diode, i.e., from about 0 V or negative (−) voltages to existing turn-on voltages. In addition, the semiconductor device 10 according to an embodiment uses an ion implantation process and an epi process and thus does not require development of new process technology.

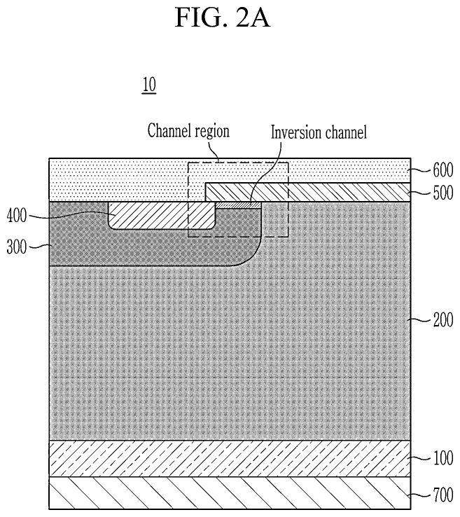

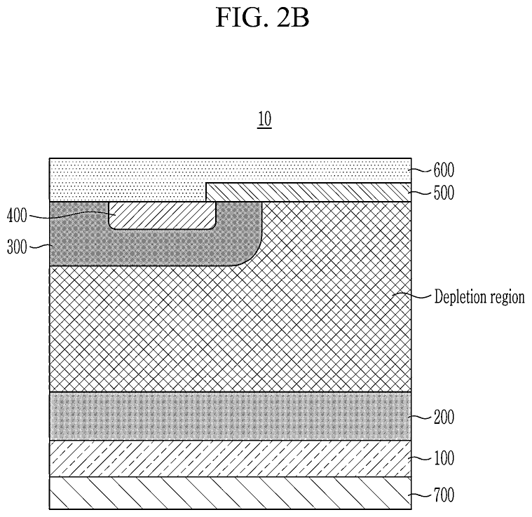

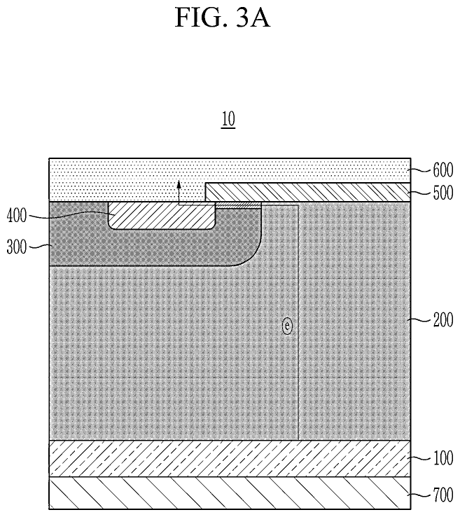

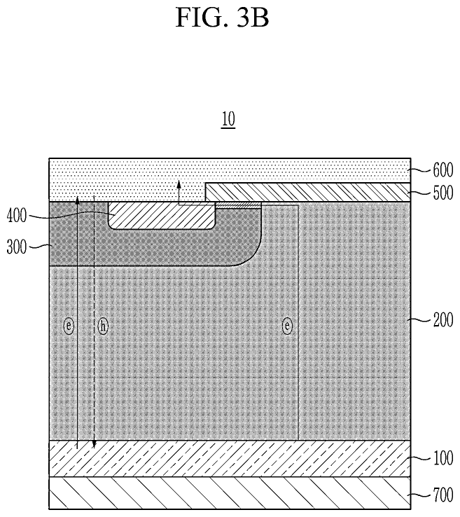

The operating mechanism of the semiconductor device 10 according to an embodiment is described in more detail below with reference to FIGS. 2A-3B.

FIG. 2A is a view schematically illustrating an operation mechanism in an on state of a semiconductor device according to an embodiment. FIG. 2B is a view schematically illustrating an operation mechanism of a semiconductor device in an off state according to an embodiment. FIG. 3A is a view schematically showing an operation mechanism under a condition of turn-on voltage (Vₜᵤᵣₙ₋ₒₙ)≤applied voltage (V_{AK})≤built-in voltage (V_{bi}) in the on state of a semiconductor device according to an embodiment. FIG. 3B is a view schematically showing an operation mechanism under a condition of built-in voltage (V_{bi})≤applied voltage (V_{AK}) in the on state of a semiconductor device according to an embodiment.

Referring to FIG. 2A, because the semiconductor device 10 according to an embodiment has an inversion channel formed in a channel region with a metal oxide semiconductor (MOS) structure in an on-state, e.g., in a region where the P region 300 is in contact with the insulating layer 500, an electron current may be conducted through the inversion channel. Accordingly, referring to FIG. 3A, the semiconductor device 10 according to an embodiment may satisfy a formula of turn-on voltage (Vₜᵤᵣₙ₋ₒₙ)≤applied voltage (V_{AK}) built-in voltage (V_{bi}) in the on-state. In addition, referring to FIG. 3B, as the PN junction is turned on, the electron current and a hole current may be conducted through the PN junction region. Accordingly, the semiconductor device 10 according to an embodiment may satisfy a formula of built-in voltage (V_{bi})≤applied voltage (V_{AK}) in the on-state. Herein, the turn-on voltage (Vₜᵤᵣₙ₋ₒₙ) is a voltage at which the inversion channel is formed and may be determined by a thickness of an oxide layer with an MOS structure and interface charges. The applied voltage (V_{AK}) is a voltage applied between terminals of the anode and the cathode, and the built-in voltage (V_{bi}) refers to a built-in voltage resulting from the PN junction.

On the other hand, referring to FIG. 2B, the semiconductor device 10 according to an embodiment, from which the inversion channel with a metal oxide semiconductor (MOS) structure is removed in an off-state, is blocked from the conduction path of the electron current. In addition, as the PN junction is turned off, the conduction path of the electron current and the hole current also is blocked. Furthermore, a breakdown voltage is formed through the PN junction and the oxide layer with the MOS structure. For example, a depletion region may be formed through a reverse voltage applied to the PN junction to block the current and form the breakdown voltage.

Accordingly, because the semiconductor device 10 according to an embodiment has a lower turn-on voltage as compared to a turn-on voltage in conventional diode structure, the semiconductor device 10 may realize diode operation without a blocking voltage. In addition, the semiconductor device 10 may increase current density in the on-state according to the conduction of the electron current due to the inversion channel, the conduction of the electron current and the hole current due to the PN junction.

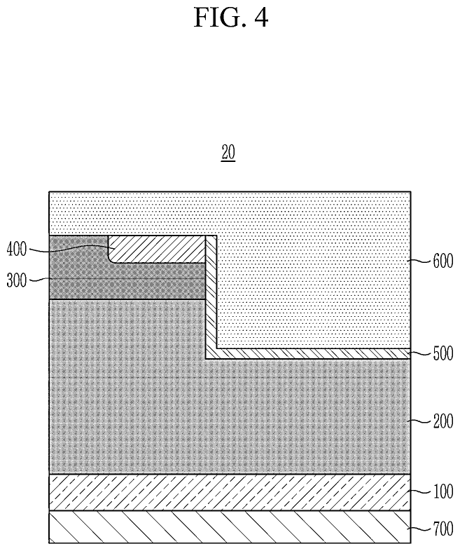

FIG. 4 is a cross-sectional view of a semiconductor device according to another embodiment.

Referring to FIG. 4, a semiconductor device 20 according to an embodiment includes a substrate 100, an epi layer 200, a P region 300, an N+ region 400, an insulating layer 500, an anode 600, and cathode 700.

The insulating layer 500 may be disposed in contact with the epi layer 200, the P region 300, and the N+ region 400. For example, the insulating layer 500, as shown in FIG. 1, may be disposed on the upper surface of the epi layer 200, the P region 300, and the N+ region 400. In addition, the insulating layer 500, as shown in FIG. 4, may be provided as a trench structure along the sides of the P region 300 and the N+ region 400 in the epi layer 200.

Referring to FIG. 4, detailed descriptions of the substrate 100, the epi layer 200, the P region 300, the N+ region 400, the insulating layer 500, the anode 600, and the cathode 700 are the same as those in FIG. 1, unless contradictory to each other. Accordingly, the detailed descriptions thereof are not repeated with reference to FIG. 4.

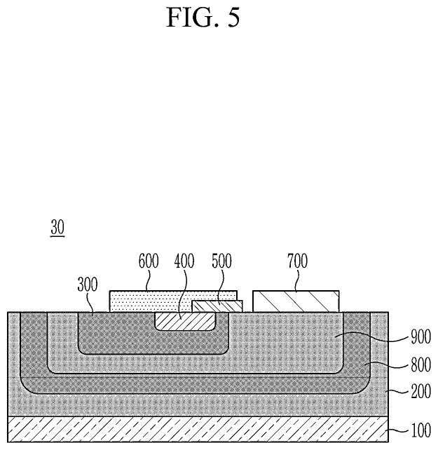

FIG. 5 is a cross-sectional view of a semiconductor device according to another embodiment.

Referring to FIG. 5, a semiconductor device 30 according to an embodiment includes a substrate 100, an epi layer 200, a P region 300, an N+ region 400, an insulating layer 500, an anode 600, and a cathode 700, and may further include a P-well region 800 and an N region 900.

The P-well region 800 may be located between the epi layer 200 and the P region 300 within the epi layer 200. In addition, the P-well region 800 may be located in a trench structure within the epi layer 200. The P-well region 800 may be located on the same line as the upper surface of the epi layer 200, an extension line of the upper surface of the P region 300, and an extension line of the upper surface of the N+ region 400.

The P-well region 800 may be formed through an ion implantation process.

The P-well region 800 may include a P type semiconductor material, for example P type silicon carbide (SiC), P type gallium nitride (GaN), P type gallium oxide (Ga₂O₃), P type diamond, P type silicon (Si), P type gallium arsenide (GaAs), P type germanium (Ge), P type aluminum nitride (AlN), or the like.

An N region 900 may be located between the P-well region 800 and the P region 300. The N region 900 may include the same material as the epi layer 200.

In the semiconductor device 30 with the structure, the P region 300 may be, for example, a P+ type.

The anode 600 is disposed on the P region 300, the N+ region 400, and the insulating layer 500, and the cathode 700 may be spaced apart in the same layer as the anode 600.

Referring to FIG. 5, detailed descriptions of the substrate 100, the epi layer 200, the P region 300, the N+ region 400, the insulating layer 500, the anode 600, and the cathode 700 may be the same as in FIG. 1, unless contradictory to each other. Accordingly, the detailed descriptions thereof are not repeated with reference to FIG. 5.

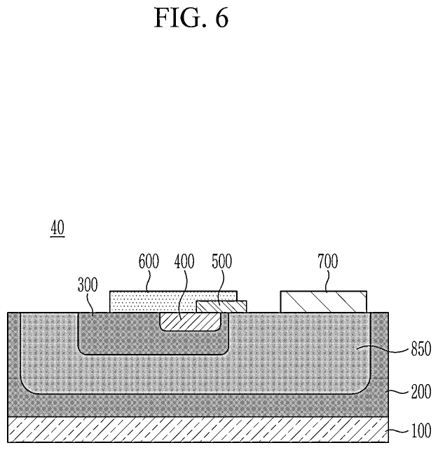

FIG. 6 is a cross-sectional view of a semiconductor device according to another embodiment.

Referring to FIG. 6, a semiconductor device 40 according to an embodiment includes a substrate 100, an epi layer 200, a P region 300, an N+ region 400, an insulating layer 500, an anode 600, and a cathode 700, and may further include an N-well region 850.

In the semiconductor device 40, the substrate 100 may be a P+ type substrate, and the epi layer 200 may be a P− type epi layer, for example.

An N-well region 850 may be disposed between the epi layer 200 and the P region 300 in the epi layer 200. In addition, the N-well region 850 may be located on the same line as the upper surface of the epi layer 200, the upper surface of the P region 300, and the upper surface of the N+ region 400.

The N-well region 850 may be formed through an ion implantation process.

The N-well region 850 may include an N-type semiconductor material, for example N-type silicon carbide (SiC), N-type gallium nitride (GaN), N-type gallium oxide (Ga₂O₃), N-type diamond, and N-type silicon (Si), N-type gallium arsenide (GaAs), N-type germanium (Ge), N-type aluminum nitride (AlN), or the like.

In the semiconductor device 40, the P region 300 may be, for example, a P+ type.

The anode 600 may be disposed on the P region 300, the N+ region 400, and the insulating layer 500, and the cathode 700 may be spaced apart in the same layer as the anode 600.

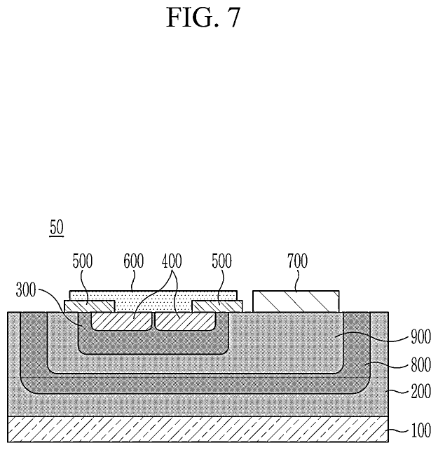

Referring to FIG. 6, detailed descriptions of the substrate 100, the epi layer 200, the P region 300, the N+ region 400, the insulating layer 500, the anode 600, and cathode 700 are the same as in FIG. 1, unless contradictory to each other. Accordingly, the detailed descriptions thereof are not repeated with reference to FIG. 6. FIG. 7 is a cross-sectional view of a semiconductor device according to another embodiment.

Referring to FIG. 7, a semiconductor device 50 according to an embodiment may include the substrate 100, the epi layer 200, the P region 300, the N+ region 400, the insulating layer 500, the anode 600, the cathode 700, the P-well region 800, and the N region 900.

For example, the semiconductor device 50 may include two N+ regions 400 and two insulating layers 500, respectively.

Referring to FIG. 7, detailed descriptions of the substrate 100, the epi layer 200, the P region 300, the N+ region 400, the insulating layer 500, the anode 600, cathode 700, the P-well region 800, and the N region 900 are the same as in FIG. 5, unless contradictory to each other. Accordingly, the detailed descriptions thereof are not repeated with reference to FIG. 7.

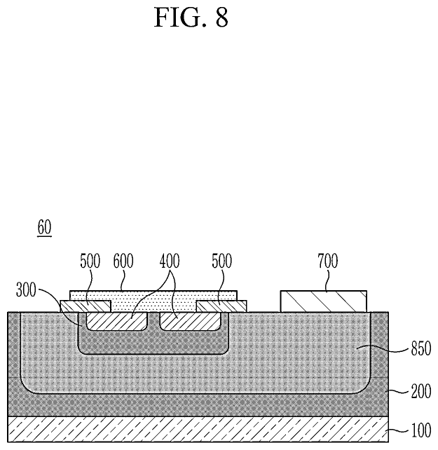

FIG. 8 is a cross-sectional view of a semiconductor device according to another embodiment.

Referring to FIG. 8, a semiconductor device 60 according to an embodiment may include the substrate 100, the epi layer 200, the P region 300, the N+ region 400, the insulating layer 500, the anode 600, the cathode 700, and the N-well region 850.

For example, the semiconductor device 60 may include two N+ regions 400 and two insulating layers 500, respectively.

Referring to FIG. 8, detailed descriptions of the substrate 100, the epi layer 200, the P region 300, the N+ region 400, the insulating layer 500, the anode 600, the cathode 700, and the N-well region 850 are the same as in FIG. 6, unless contradictory to each other. Accordingly, the detailed descriptions thereof are not repeated with reference to FIG. 8.

Hereinafter, a method for manufacturing a semiconductor device according to an embodiment is described.

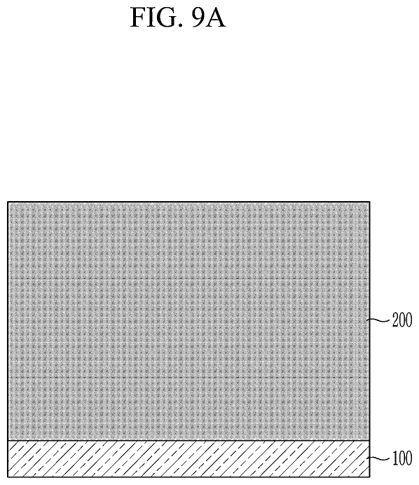

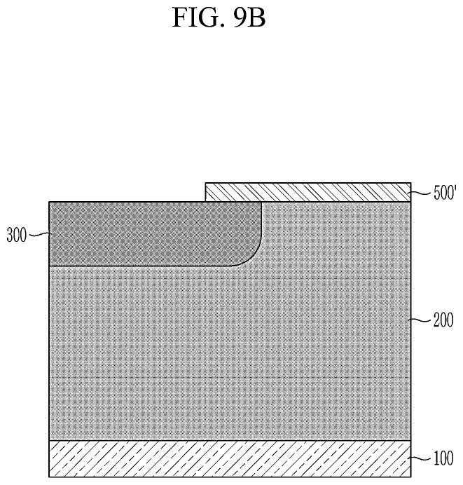

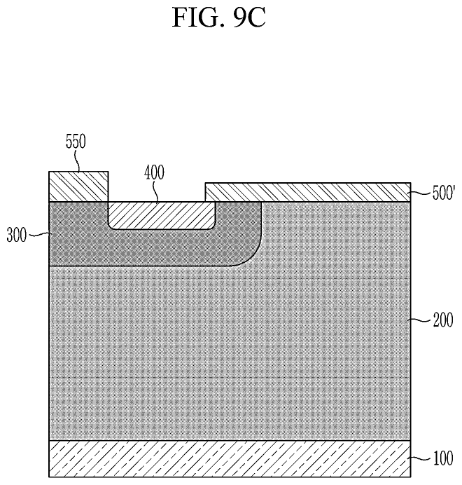

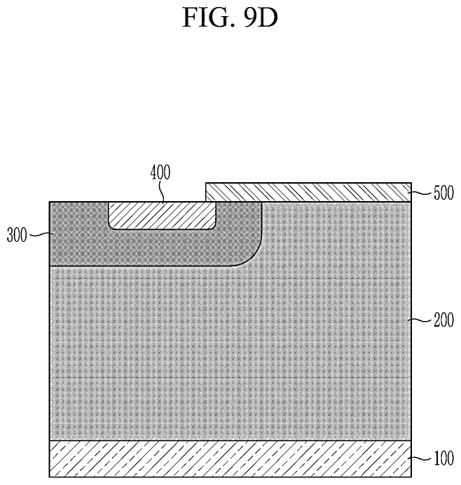

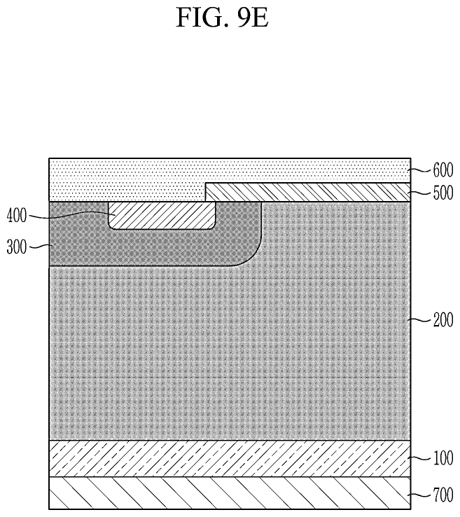

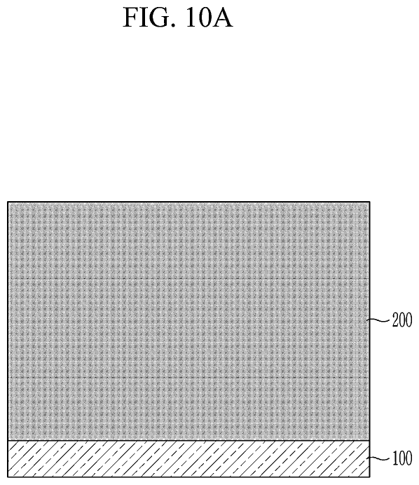

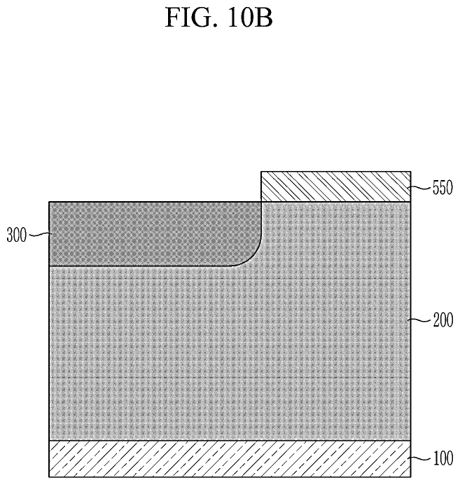

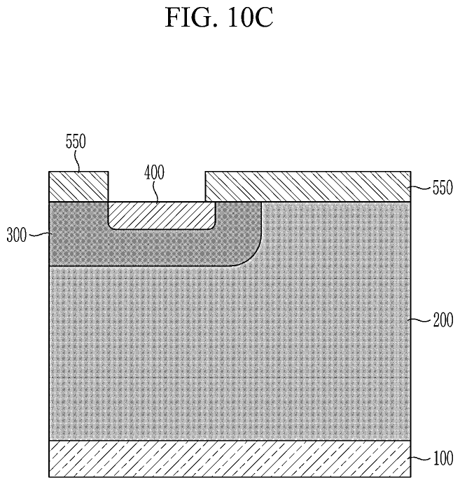

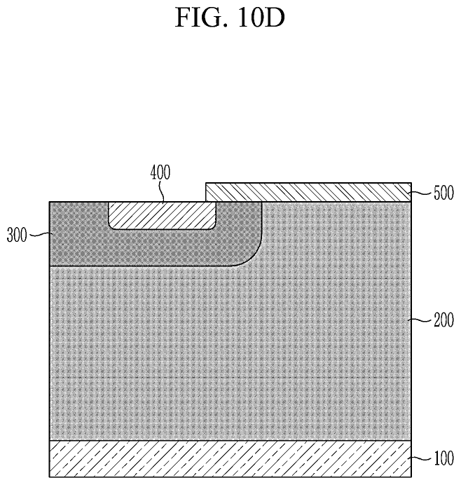

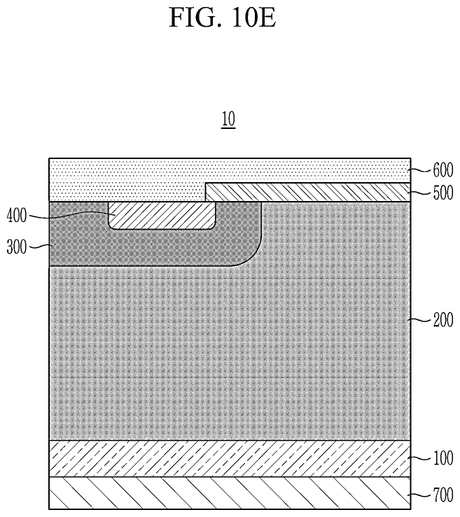

Specifically, a method of manufacturing the semiconductor device 10 shown in FIG. 1 is described with reference to FIGS. 9A-10E.

FIGS. 9A-9E are views sequentially showing a method of manufacturing a semiconductor device according to an embodiment.

Referring to FIG. 9A, the substrate 100 is prepared, and then the epi layer 200 is formed on the upper surface of the substrate 100.

Referring to FIG. 9B, the P region 300 is formed by ion implantation and heat treatment within the epi layer 200.

When forming the P region 300, before the ion implantation, a mask 500′ for patterning the P region 300 may be disposed on the epi layer 200. The mask 500′ may include the same material as the insulating layer 500. After forming the P region 300, the mask 500′ may be not removed. Rather, the mask 500′ be maintained and thus formed as the insulating layer 500.

Referring to FIG. 9C, the ion implantation into the P region 300 and a heat treatment may be performed at least one N+ region 400. The N+ region 400 may be, for example, formed by a number of N+ regions in the range of two to four N+ regions.

When forming the N+ region 400, before the ion implantation, a mask 550 for patterning the N+ region 400 may be disposed on the P region 300. The mask 550 may be removed after forming the N+ region 400.

Referring to FIG. 9D, at least one insulating layer 500 may be formed at a location in contact with the epi layer 200, the P region 300, and the N+ region 400. For example, the insulating layer 500 may be formed on the upper surface of the epi layer 200, the P region 300, and the N+ region 400. The insulating layer 500 may be, for example, formed by a number of insulating layers in the range of two to four insulating layers.

Referring to FIG. 9E, the anode 600 is formed on the P region 300, the N+ region 400, and the insulating layer 500. Subsequently, the cathode 700 is formed on the lower surface of the substrate 100.

FIGS. 10A-10E are views sequentially showing a method of manufacturing a semiconductor device according to another embodiment.

Referring to FIG. 10A, the substrate 100 is prepared, and then the epi layer 200 is formed on the upper surface of the substrate 100.

Referring to FIG. 10B, the P region 300 is formed by ion implantation and heat treatment within the epi layer 200.

When forming the P region 300, before the ion implantation, for patterning the P region 300, the mask 550 may be disposed on the epi layer 200. The mask 550 may be removed after forming the P region 300.

Referring to FIG. 10C, the ion implantation into the P region 300 and a heat treatment are performed to form at least one N+ region 400.

When forming the N+ region 400, before the ion implantation, for patterning the N+ region 400, the mask 550 on the epi layer 200 and the P region 300 may be disposed. The mask 550 may be removed after forming the N+ region 400.

Referring to FIG. 10D, at least one insulating layer 500 is formed at a location in contact with the epi layer 200, the P region 300, and the N+ region 400. For example, the insulating layer 500 may be formed on the upper surface of the epi layer 200, the P region 300, and the N+ region 400.

Referring to FIG. 10E, the anode 600 is formed on the P region 300, the N+ region 400, and the insulating layer 500, and subsequently, the cathode 700 is formed on the lower surface of the substrate 100.

The semiconductor device 20 shown in FIG. 4, may be manufactured by performing a method of manufacturing the semiconductor 10 of FIG. 1, as described above, and further forming the insulating layer 500 with a trench structure along sides of the P region 300 and the N+ region 400 in the epi layer 200.

The semiconductor device 30 shown in FIG. 5 may be manufactured by performing a method of manufacturing the semiconductor 10 of FIG. 1, as described above, and additionally forming the P-well region 800 between the epi layer 200 and the P region 300 and additionally, the N region 900 between the P-well region 800 and the P region 300 in the epi layer 200 after forming the epi layer 200 but before forming the P region 300. In addition, after forming the anode 600, the cathode 700 is spaced apart in the same layer as the anode 600 to manufacture the semiconductor device 30 shown in FIG. 5.

The semiconductor device 40 shown in FIG. 6 may be manufactured by performing a method of manufacturing the semiconductor 10 of FIG. 1, as described above, and further forming the N-well region 850 between the epi layer 200 and the P region 300 in the epi layer 200 after forming the epi layer 200 but before forming the P region 300. In addition, after forming the anode 600, the cathode 700 is spaced apart in the same layer as the anode 600 to manufacture the semiconductor device 40 shown in FIG. 6.

The semiconductor device 50 shown in FIG. 7 may be manufactured by performing a method of manufacturing the semiconductor 30 of FIG. 5, as described above, and further forming two insulating layers 500 after forming two N+ regions 400 through the ion implantation.

The semiconductor device 60 shown in FIG. 8 may be manufactured by performing a method of the semiconductor 40 of FIG. 6 as described above, and further forming two insulating layers 500 after forming two N+ regions 400 through the ion implantation.

Hereinafter, example embodiments are illustrated in more detail with reference to examples. However, these embodiments are illustrative, and the scope of the present disclosure is not limited thereto.

### Example 1 and Comparative Example 1

Example 1 is a semiconductor device manufactured to have a structure shown in FIG. 1, and Comparative Example 1 is a semiconductor device manufactured to have a structure in which a substrate, an epi layer, a P region, and an anode were disposed in order on a cathode.

### Evaluation 1: Measurement of Turn-on Voltage and On-state Current Density of Semiconductor Devices

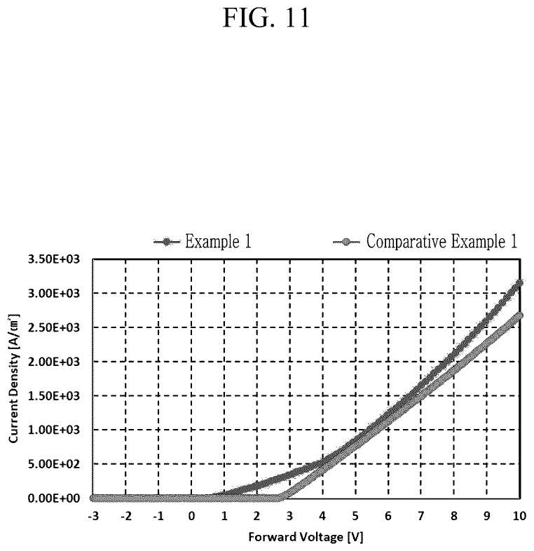

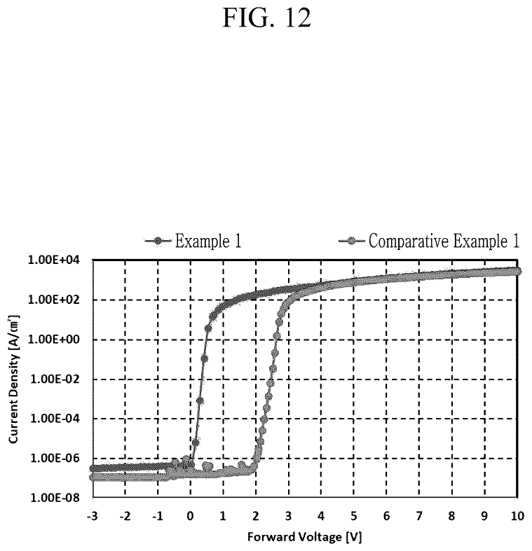

Each of the semiconductor devices of Example 1 and Comparative Example 1 were measured with respect to a turn-on voltage and on-state current density, and the results are shown in Table 1 and FIGS. 11 and 12.

The turn-on voltage was measured at current density of 0.33 A/cm², and the on-state current density was measured at each forward voltage of 1.5 V, 4.0 V, and 10 V.

TABLE 1

| | | Comparative |
|---|---|---|
| | Example 1 | Example 1 |
| Current density | 111 | 2.13E−7 |
| (A/cm²) @1.5 V | | |
| Current density | 533 | 421 |
| (A/cm²) @4.0 V | | |
| Current density | 3150 | 2680 |
| (A/cm²) @10 V | | |
| Turn-on voltage | 0.02705 | 2.0173 |
| (V) @0.33 A/cm² | | |

FIG. 11 is a linear scale graph showing the current density in the on state of the semiconductor devices according to Example 1 and Comparative Example 1. FIG. 12 is a log scale graph showing the current density in the on state of the semiconductor devices according to Example 1 and Comparative Example 1.

Referring to Table 1 and FIGS. 11 and 12, in the semiconductor device of Example 1, compared with the semiconductor device of Comparative Example 1, the turn-on voltage is decreased, and the on-state current density is increased.

Specifically, in Example 1, compared with Comparative Example 1, the turn-on voltage is decreased to 98.7% and reaches almost 0 V. In addition, the decreased turn-on voltage and removal of a cut-in voltage increased usable regions, so that the semiconductor device according to some embodiments might be applied in more various fields. For reference, if an operating point is below a turn-on voltage, it is impossible to use a semiconductor device.

In addition, in Example 1, compared with Comparative Example 1, on-state current density is increased by at least 26.6%, which leads to conduction of an electron current by an inversion channel and conduction of the electron current and a hole current by PN junction. As a result, an on-state current in Example 1 is increased. In addition, in Example 1, compared with Comparative Example 1, a chip area was reduced by 21.1%, improving the number of semiconductor devices per unit wafer and a yield of the semiconductor devices and thereby, resulting in cost reduction.

While inventive concepts of the present disclosure have been described in connection with example embodiments, it should be understood that the present disclosure is not limited to the disclosed embodiments. On the contrary, the present disclosure is intended to cover various modifications and equivalent arrangements included within the spirit and scope of the appended claims.

### DESCRIPTION OF SYMBOLS

10, 20, 30, 40, 50, 60: semiconductor device
100: substrate
200: epi layer
300: P region
400: N+ region
500: insulating layer
600: anode
700: cathode
800: P-well region
850: N-well region
900: N region

What is claimed is:

1. A semiconductor device, comprising:
a substrate;
an epi layer on an upper surface of the substrate;
a P region located within the epi layer;
at least one N+ region located within the P region;
at least one insulating layer in contact with the epi layer, the P region, and the at least one N+ region; and
an anode provided on the P region, the at least one N+ region, and the at least one insulating layer.

2. The semiconductor device of claim 1, wherein the at least one insulating layer is one of:
located on upper surfaces of the epi layer, the P region, and the at least one N+ region; or
located in a trench structure along sides of the P region and the at least one N+ region within the epi layer.

3. The semiconductor device of claim 1, wherein the substrate includes at least one of an N+ type substrate, a P+ type substrate, or any combination thereof.

4. The semiconductor device of claim 1, wherein the epi layer includes at least one of an N− type epi layer, a P− type epi layer, or any combination thereof.

5. The semiconductor device of claim 1, wherein the semiconductor device further includes a P-well region or an N-well region located between the epi layer and the P region within the epi layer.

6. The semiconductor device of claim 5, wherein the P region includes a P+ type.

7. The semiconductor device of claim 1, wherein the semiconductor device further includes:
a P-well region located between the epi layer and the P region within the epi layer; and
an N region located between the P-well region and the P region.

8. The semiconductor device of claim 7, wherein the P region includes a P+ type.

9. The semiconductor device of claim 1, wherein:
the at least one N+ region includes a number of N+ regions in the range of two to four N+ regions; and
the at least one insulating layer includes a number of insulating layers in the range of two to four insulating layers.

10. The semiconductor device of claim 1, wherein the semiconductor device further includes a cathode, and wherein the cathode is located on a lower surface of the substrate or is spaced apart in a same layer as the anode.

11. The semiconductor device of claim 1, wherein, in an on state, an inversion channel is formed in a portion where the P region and the at least one insulating layer contact each other.

12. A method of manufacturing a semiconductor device, the method comprising:
forming an epi layer on an upper surface of a substrate;
forming a P region in the epi layer through ion implantation;
forming at least one N+ region within the P region through ion implantation;
forming at least one insulating layer at a location in contact with the epi layer, the P region, and the at least one N+ region; and
forming an anode on the P region, the at least one N+ region, and the at least one insulating layer.

13. The method of claim 12, wherein forming the P region includes patterning by placing a mask on the epi layer before the ion implantation.

14. The method of claim 12, wherein forming the at least one N+ region includes patterning by placing a mask on the P region and the epi layer before the ion implantation.

15. The method of claim 12, wherein forming the at least one insulating layer includes one of:
forming the at least one insulating layer on upper surfaces of the epi layer, the P region, and the at least one N+ region; or
forming the at least one insulating layer in a trench structure along sides of the P region and the at least one N+ region within the epi layer.

16. The method of claim 12, further comprising, after forming the epi layer and before forming the P region, forming a P-well region or an N-well region within the epi layer between the epi layer and the P region.

17. The method of claim 12, further comprising, after forming the epi layer and before forming the P region:
forming a P-well region within the epi layer between the epi layer and the P region; and
forming an N region between the P-well region and the P region.

18. The method of claim 12, wherein:
forming the at least one N+ region includes forming a number of N+ regions in the range of two to four N+ regions through ion implantation in the P region, and
forming the at least one insulating layer includes forming a number of insulating layers in the range of two to four insulating layers on upper surfaces of the epi layer, the P region, and the N+ region.

19. The method of claim 12, wherein further comprising, after forming the anode, forming a cathode on a lower surface of the substrate or spaced apart in a same layer as the anode.
